(19) United States
(12) Patent Application Publication
(10) Pub. No.: US 2026/0367153 A1
(43) Pub. Date: Nov. 19, 2026

(54) BATTERY MANAGEMENT DEVICE AND A METHOD OF CONTROLLING THE SAME

(71) Applicants: HYUNDAI MOTOR COMPANY, Seoul (KR); KIA CORPORATION, Seoul (KR)

(72) Inventors: Si Joong Kim, Hwaseong-si (KR); Min Jun Park, Hwaseong-si (KR); Hyun Jun Jang, Hwaseong-si (KR); Tae Kyu Kang, Hwaseong-si (KR)

(73) Assignees: HYUNDAI MOTOR COMPANY, Seoul (KR); KIA CORPORATION, Seoul (KR)

(21) Appl. No.: 19/326,434

(22) Filed: Sep. 11, 2025

(30) Foreign Application Priority Data
May 19, 2025 (KR) 10-2025-0064793

(51) Int. Cl. G01R 31/367; B60L 58/12; G01R 31/3842; H01M 10/42

(52) U.S. Cl. CPC G01R 31/367; G01R 31/3842; H01M 10/425; B60L 58/12; B60L 2240/547; B60L 2240/549; H01M 2010/4271

(57) ABSTRACT

A battery management device and a method of controlling the same correct errors in the state of charge (SOC) of a vehicle battery. A battery management device includes a battery, a sensor configured to measure a state of the battery, and a controller. The controller is configured to determine a first SOC of the battery based on the state of the battery cumulatively measured through the sensor. The controller is further configured to correct the first Soc based on a second SOC of the battery determined based on a pre-trained model with selective use of a current and a voltage of the battery based on whether the battery is being charged.

### CROSS-REFERENCE TO RELATED APPLICATION

The present application claims the benefit of priority to Korean Patent Application No. 10-2025-0064793, filed on May 19, 2025, the entire disclosure of which is incorporated herein by reference.

### BACKGROUND OF THE DISCLOSURE

### Field of the Disclosure

Various aspects of the present disclosure relate to a battery management device and a method of controlling the same for correcting errors in the state of charge (SOC) of a vehicle battery.

### Description of the Related Art

In recent years, technical requirements for batteries, which are key components of electric vehicles, have diversified. In particular, there is growing interest in batteries that may provide safety, increased lifespan, and cost-effectiveness.

Among such batteries, some batteries have a 2-phase characteristic depending on the electrode material. The 2-phase characteristic refers to a discharge curve that includes a flat range where the voltage remains constant during the discharge process of the battery, followed by a range where the voltage rapidly decreases. These characteristics arise from the coexistence of two different phases during the electrochemical reaction over a certain range within which a phase transition occurs. Batteries having a 2-phase characteristic may exhibit a flat voltage over a wide SOC range. A representative example of batteries having a 2-phase characteristic are lithium iron phosphate (LFP) batteries.

LFP batteries are being rapidly adopted for use in electric vehicles due to their high thermal stability, long battery life, and economic advantages that do not require the use of expensive metals such as cobalt or nickel.

However, due to the above-mentioned 2-phase characteristic, LFP batteries exhibit little variation in open-circuit voltage (OCV) across most of the SOC range. Therefore, there are limitations for accurately estimating the state of charge of 2-phase characteristic batteries by using the voltage value alone. As a result, current methods for estimating the SOC of the 2-phase characteristic batteries may use complex estimation algorithms. Further, there are additional technical considerations such as initial state setting, accumulated error, and computational complexity.

The above description of the related art should enhance understanding of the background of the present disclosure and should not be construed as an admission that such art is known to those of ordinary skill in the art.

### SUMMARY

Various aspects of the present disclosure are directed to providing a battery management device and a method of controlling the same for correcting errors in the state of charge (SOC) of a vehicle battery.

In particular, complementary techniques for improving SOC estimation accuracy have been provided to enhance the practical efficiency of batteries having a 2-phase characteristic.

The technical objects of various aspects of the present disclosure are not limited to the technical objects mentioned above. Other technical objects not mentioned should be clearly understood by those of ordinary skill in the art to which the present disclosure pertains from the following description.

A battery management device according to an embodiment of the present disclosure may include a battery, a sensor configured to measure a state of the battery, and a controller. The controller may be configured to determine a first SOC of the battery based on the state of the battery cumulatively measured through the sensor. The controller may be configured to correct the first Soc based on a second SOC of the battery determined based on a pre-trained model with selective use of a current and a voltage of the battery based whether the battery is being charged.

In an embodiment, the voltage may include voltages at respective idle times. Each idle time of the respective idle times includes a time elapsed after completion of charging of the battery. The current may include a charging current during charging of the battery.

In an embodiment, the pre-trained model may be trained to determine an SOC of the battery based on a relationship between the charging current of the battery and voltages at respective idle times.

In an embodiment, the pre-trained model may include information on a difference between the second SOC and a third Soc determined based on results of an evaluation of a battery state performed during manufacturing of the battery. The second SOC may be determined based on the battery state being used as a reference.

In an embodiment, the controller may be configured to determine, based on the battery being charged, the second SOC among a plurality of SOCs determined based on the pre-trained model using the charging current as an SOC that satisfies a preset criterion for a difference from the third SOC.

In an embodiment, the controller may be configured to, based on the charging of the battery being completed, determine the second SOC based on the pre-trained model using the charging current and voltages at respective idle times.

In an embodiment, the controller may be configured to correct the first soc based on whether a difference between the first SOC and the second SOC satisfies a preset criterion.

In an embodiment, the controller may be configured to correct the first soc until the first SOC converges to the second soc based on a preset rate of SOC change per unit time.

In an embodiment, the preset rate of SOC change per unit time may be determined based on a difference between the first SOC and the second SOC.

In addition, a method of controlling a battery according to an embodiment of the present disclosure may include determining, by a controller, a first SOC of the battery based on a state of the battery cumulatively measured through a sensor that measures the state of the battery. The method may further include correcting, by the controller, the first Soc based on a second SOC of the battery determined based on a pre-trained model with selective use of a current and a voltage of the battery based on whether the battery is being charged.

In an embodiment, the voltage may include voltages at respective idle times. Each idle time of the respective idle times is a time elapsed after completion of charging of the battery. The current may include a charging current during charging of the battery.

In an embodiment, the pre-trained model may be trained to determine an SOC of the battery based on a relationship between the charging current of the battery and voltages at respective idle times.

In an embodiment, the pre-trained model may include information on a difference between the second SOC and a third SOC determined based on results of an evaluation of the battery state performed during manufacturing of the battery. The battery state may be used as a reference when determining the second SOC.

In an embodiment, correcting the first SOC based on the second SOC of the battery may include determining, based on the battery being charged, by the controller, the second SOC among a plurality of SOCs determined based on the pre-trained model using the charging current, as an SOC that satisfies a preset criterion for a difference from the third SOC.

In an embodiment, correcting the first SOC based on the second SOC of the battery may include determining, based on the charging of the battery being completed, by the controller, the second SOC based on the pre-trained model using the charging current and voltages at respective idle times.

In an embodiment, correcting the first Soc by the controller may include correcting, by the controller, the first SOC based on whether a difference between the first SOC and the second SOC satisfies a preset criterion.

In an embodiment, correcting the first Soc by the controller may include correcting, by the controller, the first SOC until the first SOC converges to the second SOC based on a preset rate of SOC change per unit time.

In an embodiment, the preset rate of SOC change per unit time may be determined based on a difference between the first SOC and the second SOC.

As noted above, there are limitations for accurately estimating the state of charge of 2-phase characteristic batteries by using the voltage value alone. As a result, methods for estimating the SOC of the 2-phase characteristic batteries may use complex estimation algorithms such as a coulomb counting method or Kalman filter. In an embodiment of the present disclosure, the battery management device may determine an SOC of the battery based on a pre-trained model by selectively using a charging current of the battery and voltages at respective idle times. The SOC determined in this manner may have higher accuracy compared to an SOC determined using a method such as a coulomb counting method and may provide more reliable SOC information.

The technical effects that may be obtained by the embodiments of the present disclosure are not limited to those described above. Other effects not described in the present disclosure should be apparent to those of ordinary skill in the art from the description below.

### BRIEF DESCRIPTION OF THE DRAWINGS

FIG. 1 is a graph showing a nonlinear relationship between the state of charge (SOC) of a battery and open circuit voltage (OCV) according to an embodiment of the present disclosure.

FIG. 2 is a block diagram showing an example of a battery management device configuration according to an embodiment of the present disclosure.

FIG. 3 is a diagram showing an electrical equivalent circuit of a battery in which a polarization phenomenon occurs according to an embodiment of the present disclosure.

FIG. 4 is a graph showing the change in battery voltage over time during charging of the battery and after completion of the charging according to an embodiment of the present disclosure.

FIG. 5 is a flow diagram showing a process in which a mathematical model is trained according to an embodiment of the present disclosure.

FIG. 6 is a flow diagram showing a process in which a controller corrects the SOC of the battery according to an embodiment of the present disclosure.

FIG. 7 is a graph showing a process in which the controller determines polarization of the battery based on an idle time after battery charging is completed according to an embodiment of the present disclosure.

FIG. 8 shows a flow diagram of a process in which the controller corrects a first Soc based on a second SOC according to an embodiment of the present disclosure.

Hereinafter, embodiments of the present disclosure are described in detail with reference to the accompanying drawings. It may be understood that the accompanying drawings are not necessarily to scale, presenting a simplified representation of various features illustrative of the basic principles of the present disclosure. The predetermined design features of the present disclosure as included herein, including, for example, various dimensions, orientations, locations, and shapes are determined in part by the particularly intended application and environment.

The same constituent elements in the drawings are denoted by the same reference numerals and a repeated or duplicative description of the same elements has been omitted.

### DETAILED DESCRIPTION OF THE DISCLOSURE

Various structural or functional descriptions of the embodiments disclosed in the present disclosure are provided to illustrate various embodiments. However, embodiments of the present disclosure may be implemented in various different ways.

Various embodiments according to the present disclosure may be subject to various modifications and take various forms. Therefore, various embodiments are illustrated in the drawings and are described in detail below. However, the present disclosure is not limited to the embodiments described therein. It should be understood that the present disclosure may include all modifications, equivalents, and substitutes without departing from the spirit or technical scope of the present disclosure.

Unless otherwise defined, all terms used herein, including technical and scientific terms, have the same meaning as commonly understood by those of ordinary skill in the art. Such terms as those defined in a generally used dictionary may be interpreted as having meanings consistent with the context of the relevant field of art and should not be interpreted to have ideal or overly formal meanings unless explicitly defined in the present disclosure.

Hereinafter, embodiments of the present disclosure are described in detail with reference to the accompanying drawings. In the following drawings, the same reference numerals are used throughout to designate the same or equivalent elements, even though the elements are shown in different drawings and redundant descriptions thereof are omitted.

In the description of the following embodiments, the term “preset” means that the numerical value of a parameter is determined in advance when the parameter is used in a process or algorithm. The numerical value of the parameter may be set when the process or algorithm is started or while the process or algorithm is being performed, depending on the embodiment.

As used in the description below, suffixes “module” and “part” for a component are used or interchangeably used solely for ease of preparation of the specification, and do not have different meanings and each of them does not function by itself. When a component, device, element, part, unit, module or the like of the present disclosure is described as having a purpose or performing an operation, function, or the like, the component, device, or element should be considered herein as being “configured to” meet that purpose or to perform that operation or function. Each “part”, “unit”, “module”, “component”, “device”, “element”, and the like may separately embody or be included with a processor and a memory, such as a non-transitory computer readable media, as part of the apparatus.

In describing the disclosed embodiments, when a detailed description of the known related art is determined to obscure the gist of the disclosed embodiments, such detailed description is omitted herein. In addition, the accompanying drawings are provided merely to facilitate understanding of the disclosed embodiments and are not intended to limit the technical spirit of the present disclosure. It should be understood that all modifications, equivalents, and substitutes falling within the spirit and scope of the present disclosure are included.

Terms including ordinal numbers such as first, second, and the like used herein may be used to describe various components, but the components are not limited by these terms. The terms are used only for the purpose of distinguishing one component from another component.

When a component is referred to as being “connected” or “coupled” to another component, it should be understood that not only the component may be directly connected or coupled to other components, but also that another component may be present or exist therebetween. Conversely, when a component is referred to as being “directly connected” or “directly coupled” to any other component, it should be understood that no other component exists therebetween.

Unless the context clearly dictates otherwise, the singular form includes the plural form.

In the present disclosure, the terms “comprising,” “having,” or the like are used to specify that a feature, a number, a step, an operation, a component, an element, or a combination thereof described herein exists. The terms do not preclude the possibility of the presence or addition of one or more other features, numbers, steps, operations, components, elements, or combinations thereof.

In addition, a unit or control unit included in various components such as a motor control unit (MCU) and a hybrid control unit (HCU), is a term used to refer to a specifically configured controller that controls various functions of a vehicle, but does not mean a generic function unit.

A controller may include a communication device for communicating with other control units or sensors to control a corresponding function, a non-transitory memory for storing an operating system, a logic command, and input/output information, and one or more processors for performing determination, calculation, and decision operations which are necessary for controlling the corresponding function.

Various embodiments of the present disclosure provide a method for more accurately estimating the SOC of a battery having a 2-phase characteristic. Hereinafter, the battery having a 2-phase characteristic is assumed to be a lithium iron phosphate (LFP) battery. However, this is for convenience of description, and the method may be applied to any battery with any electrode material as long as the battery has a 2-phase characteristic.

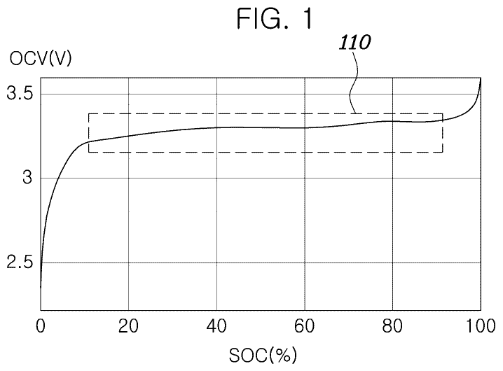

FIG. 1 is a graph showing a nonlinear relationship between the state of charge (SOC) of a battery and an open circuit voltage (OCV) according to an embodiment of the present disclosure.

Referring to FIG. 1, it should be noted that the LFP battery maintains a generally flat voltage within an SOC range 110 between 10% and 90%. As such, if the voltage changes a small amount over a wide SOC range, it may be difficult for a battery management system (BMS) to accurately estimate the SOC of the battery using voltage values alone.

As described above, if the BMS has difficulty to accurately estimate the SOC of the battery, errors may occur in the estimated SOC, which may lead to inaccurate charge and discharge control by the BMS, potentially degrading the performance of the battery. For example, if the BMS incorrectly recognizes the SOC of the battery as higher than the actual value, the system may mistakenly assume that the battery has sufficient remaining capacity, which may ultimately lead to over discharge of the battery. Conversely, if the BMS incorrectly recognizes the SOC of the battery as lower than the actual value, the system may prematurely stop discharging the battery despite sufficient remaining battery energy, which may result in underutilization of the available battery energy and reduced battery usage efficiency. Accordingly, a battery management device applicable to the embodiments of the present disclosure provides a method for more accurately determining the Soc by utilizing a mathematical model trained to estimate the SOC based on polarization data of the battery measured under various conditions.

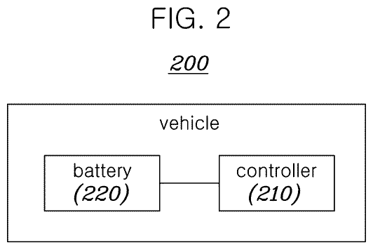

FIG. 2 is a block diagram showing an example of a battery management device configuration according to an embodiment of the present disclosure.

Referring to FIG. 2, a vehicle 200, according to an embodiment of the present disclosure, may include a controller 210 and a battery 220. Each component is described in more detail below. The controller 210 may be implemented by a processor as described below.

The controller 210 may collect and analyze state information of the battery 220 in real time to ensure efficient and stable operation of the battery 220. Specifically, the controller 210 may continuously monitor key state variables of the battery 220, such as voltage, current, and temperature, and utilize various methods based on these variables to determine the SOC of the battery 220. For example, in an embodiment of the present disclosure, the controller 210 may measure, in real time, the current applied to or discharged from the battery 220 through measurement hardware devices such as a current sensor (not shown). The controller 210 may determine the cumulative current amount by integrating the measured current value over time. The controller 210 may determine the SOC of the battery (hereinafter referred to as “first SOC”) based on the cumulative current amount. However, a coulomb counting method for determining the SOC of the battery 220 as described above is not necessarily limited thereto.

As described above, the controller 210 may perform the functions of the BMS. In an embodiment of the present disclosure, the controller 210 may be positioned either within or external to the BMS and may include control devices that constitute the BMS or perform equivalent functions. In addition, in another embodiment of the present disclosure, the controller 210 may be in the form of a BMS or include equivalent functions thereof. In some embodiments, the controller 210 may implement the BMS. However, this is merely an example provided to describe the controller 210 and is not necessarily limited thereto. In addition, the first Soc may be determined by the controller 210 using the coulomb counting method. The first SOC may differ from the actual SOC. Specifically, the coulomb counting method estimates the Soc by integrating the current over a certain period. This method may be sensitive to an initially set SOC value and may accumulate errors during the process of integrating the current due to external factors such as noise from the current sensor and temperature variations. Accordingly, the first SOC determined by the controller 210 using the coulomb counting method may be corrected to match the actual SOC.

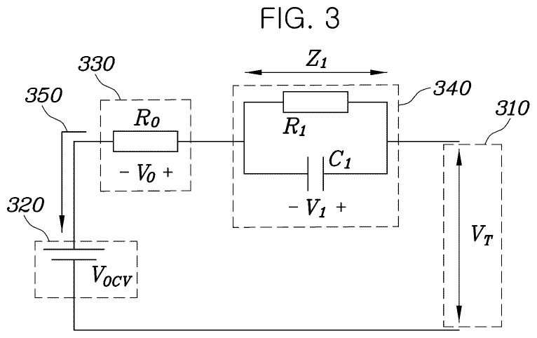

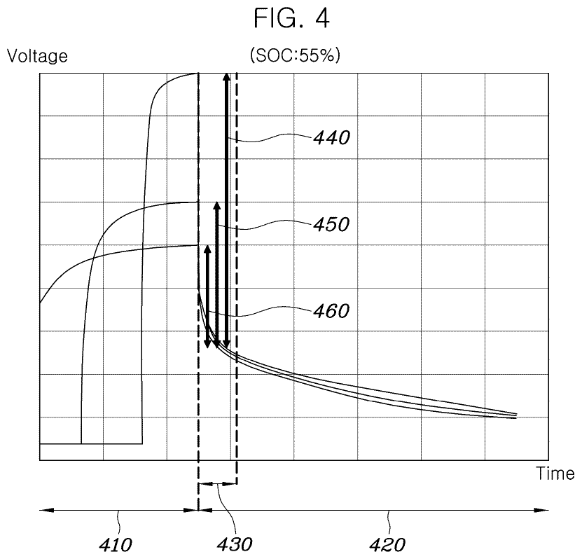

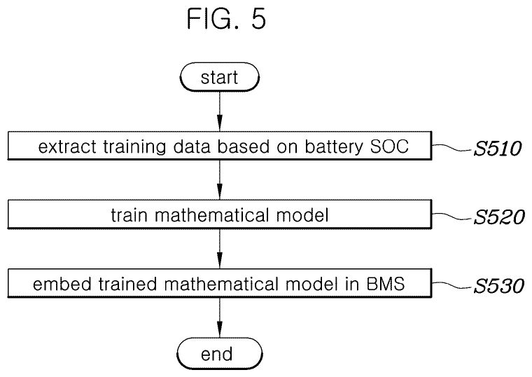

To correct the first Soc, a reference SOC may be used. In an embodiment of the present disclosure, the controller 210 may determine a reference SOC (hereinafter referred to as “second SOC”) by using a mathematical model trained based on polarization data of the battery 220 measured under various conditions. The controller 210 may correct the first SOC based on the reference SOC. The polarization of the battery 220 may refer to a difference between the theoretical voltage and the actual voltage of the battery 220 occurring during charging or discharging of the battery 220. This difference may occur due to ion transport resistance within the electrolyte, delayed electrode surface reactions, internal resistance, and the like. Since these factors causing polarization of the battery 220 are influenced by the charging current and SOC of the battery 220, the magnitude of polarization may also vary depending on the charging conditions of the battery 220. Accordingly, in an embodiment of the present disclosure, the data on which the mathematical model is trained may include information on the idle time determined based on the combination of the charging current and the SOC of different batteries 220, and the polarization of the battery 220 measured at the corresponding idle time. The mathematical model may quantitatively represent the nonlinear relationship among these elements. The idle time here may refer to the elapsed time after the charging of the battery 220 is completed. However, this is an embodiment and is not necessarily limited thereto. Referring to FIGS. 3 and 4 described below, the polarization of the battery 220 is described, followed by a more detailed description of a process by which the mathematical model is trained with reference to FIG. 5.

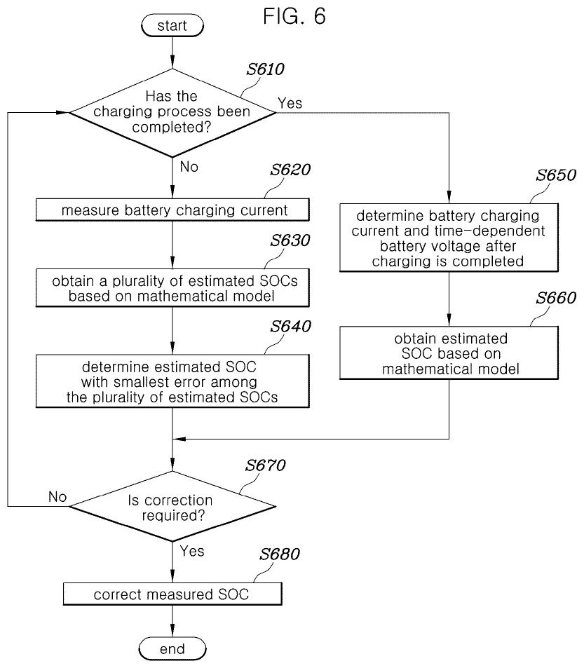

The second SOC determined based on the above-described trained mathematical model may be closer to the actual SOC, as the second SOC is not affected by the initially set SOC value and is less affected by cumulative error caused by the current sensor compared to the first SOC determined by the coulomb counting method. Accordingly, the controller 210 may improve the accuracy of the first Soc by correcting the first SOC to match the second SOC, which has higher reliability and accuracy. A process by which the controller 210 corrects the first SOC is specifically described with reference to FIG. 6 described below.

The battery 220 may be a battery that includes an electrode material having a two-phase characteristic. For example, in an embodiment of the present disclosure, the battery 220 may be an LFP battery, which offers high stability even in high-temperature environments, exhibits minimal performance degradation over long-term use, and maintains uniform output characteristics, thereby demonstrating excellent durability and reliability. However, as described above, the LFP battery may exhibit a flat voltage over a wide SOC range. Therefore, the SOC determined based on the voltage of the LFP battery may not be accurate. Accordingly, in an embodiment of the present disclosure, a correction method is provided to more precisely determine the SOC of the battery 220 by utilizing the above-described trained mathematical model.

FIG. 3 is a diagram showing an electrical equivalent circuit in which a polarization phenomenon occurs in the battery 220 according to an embodiment of the present disclosure.

Referring to FIG. 3, based on the battery 220 being in a charging state, an external current 350 is applied to the battery 220. In this situation, the actual voltage V_{T} 310 of the battery 220 measured from outside may be defined as the sum of the battery's open-circuit voltage V_{OCV} 320, the voltage V₀ 330 caused by internal resistance R₀, and the voltage V₁ 340 generated in a circuit where the polarization resistance R₁ and polarization capacitance C₁ are connected in parallel. Each voltage V_{T}, V_{OCV}, V₀, V₁ and component R₀, R₁, C₁ is described in more detail below.

As shown in FIG. 3, V_{OCV} 320 is the voltage measured when no current flows through the battery 220. R₀ represents the resistive component caused by the internal materials of the battery. The resulting voltage drop V₀ may be the product of the charging current 350. R₀. R₁ represents the energy barrier required for actual chemical reactions occurring inside the battery 220, modeled as electrical resistance. C₁ represents the electric double layer effect formed at the electrode-electrolyte interface. R₀, R₁, and C₁ are equivalent circuit components representing various electrochemical effects caused by factors that generate the polarization of the battery 220 described above, such as ion transport resistance in the electrolyte, reaction delays at the electrode surface, and internal resistance.

Referring to the equivalent circuit shown in FIG. 3, it may be seen that the polarization of the battery 220 is the sum of V₀ and V₁, and may vary depending on the current 350 flowing through the battery. In addition, the components R₀, R₁, and C₁ that affect the polarization of the battery 220 may vary according to the SOC of the battery 220. Specifically, if the SOC of the battery 220 is low, electrochemical reactions may not occur smoothly due to a lack of reactive ions in the electrode of the battery 220, which may increase R₁, and the formation of the electric double layer may be unstable due to non-uniform ions at the electrode-electrolyte interface, which may decrease C₁. In addition, the conductivity of the electrode material of the battery 220 may decrease, which may increase R₀. On the other hand, if the SOC of the battery 220 is high, the electrode of the battery 220 is nearly saturated with ions, so the insertion of additional ions becomes difficult. As a result, the electrochemical reaction slows down, and R₁ may increase. In addition, the reaction efficiency at the electrode-electrolyte interface may also decrease, which may decrease C₁. Further, excessive accumulation of ions in the electrode of the battery 220 may lead to inefficient electron transfer on the electrode surface, which may increase R₀.

Accordingly, the polarization of the battery 220 may vary depending on the SOC of the battery 220 and the current flowing through the battery 220. With reference to FIG. 4, changes in the polarization of the battery 220 at different idle times in response to changes in the charging current of the same battery 220 at a given SOC are described in detail below via a graph.

FIG. 4 is a graph showing the voltage change of the battery 220 over time during charging of the battery 220 and after completion of the charging according to an embodiment of the present disclosure.

The graph illustrated in FIG. 4 shows an example in which the battery 220 has an SOC of 55% at the time the charging of the battery 220 is completed, but this is an embodiment and is not necessarily limited thereto. Referring to FIG. 4, if the battery 220 is charging in state 410, current is applied to the battery 220, so the voltage measured at the battery 220 may increase. If charging of the battery 220 is completed in state 420, no current flows through the battery 220, so the voltage measured at the battery 220 may decrease. However, the reason the voltage does not drop abruptly in a stepwise manner but gradually decreases over a short period of time is that the charge stored in the polarization capacitance of the battery 220 is slowly discharged over time.

In an embodiment of the present disclosure, the training data used to train the mathematical model may include a dataset, which includes various combinations of the respective values for the SOC at the time the charging of battery 220 is completed, the charging current of the battery 220, the idle time, and the polarization measured at the corresponding idle time. The mathematical model may use such combination data to train on a nonlinear relationship between input variables and output variables and form an estimation model based thereon. Based on the graph shown in FIG. 4, there are a total of three types of training data used to train the mathematical model in an embodiment of the present disclosure. Specifically, FIG. 4 shows that three different charging currents are applied to the battery 220 when the SOC is 55% at the time when charging of battery 220 is completed. In addition, polarization 440, 450, 460 of the battery 220 corresponding to each charging current is measured at the same idle time 430, and based on this, a total of three types of training data are determined. However, this is merely an example provided to describe the concept of the data on which the mathematical model is trained in an embodiment of the present disclosure and is not necessarily limited thereto.

In addition, the higher the current applied to the battery 220, the higher the current that flows through the circuit in which the internal resistance R₀, the polarization resistance R₁, and the polarization capacitance C₁ of the battery 220 are configured in parallel, and accordingly, the voltage generated in the circuit may also increase. This may indicate that the polarization increases. Accordingly, referring to FIG. 4, it may be seen that if the charging current of the battery 220 is the highest, the polarization 440 of the battery 220 measured at the idle time is also the highest, and if the charging current of the battery 220 is the lowest, the polarization 460 of the battery 220 measured at the idle time is also the lowest. The polarization 440, 450, and 460 of the battery 220 may be defined as the difference between the voltage measured at the time the charging of the battery 220 is completed and the voltage measured at the idle time. The polarization voltage may be easily determined by the controller 210.

Based on the detailed description above with reference to FIGS. 3 and 4 regarding the interrelationship among the SOC of the battery 220, the charging current, the idle time, and the polarization of the battery 220 determined at the corresponding idle time, a training process of the mathematical model according to an embodiment of the present disclosure is described below.

FIG. 5 is a flow diagram showing an example of a process in which a mathematical model is trained according to an embodiment of the present disclosure.

Referring to FIG. 5, training data for the mathematical model may first be determined through empirical measurement (S510). As described above, in an embodiment of the present disclosure, the data on which the mathematical model is trained may include information on the SOC of the battery 220 at the time the charging of the battery 220 is completed, the charging current of the battery 220, the idle time, and the polarization of the battery 220 at the corresponding idle time.

Subsequently, the mathematical model may quantitatively represent the complex relationships among the four elements described above by training on the nonlinear relationship among these elements (S520). For example, in an embodiment of the present disclosure, the trained mathematical model may be utilized by the controller 210 to receive the charging current of the battery 220, the idle time, and the polarization determined at the corresponding idle time as input values, and based on these, determine the SOC of the battery 220 corresponding to the input combination.

The mathematical model trained as described above may be embedded in the controller 210 (S530). As described above, the controller 210 may determine a second SOC based on the embedded mathematical model and correct a first SOC based on the determined second SOC. The correction of the first SOC is described in more detail with reference to FIG. 6 below.

FIG. 6 shows a flow diagram of a process in which a controller 210 corrects the SOC of the battery 220 according to an embodiment of the present disclosure.

Referring to FIG. 6, the controller 210 may first determine whether charging of the battery 220 is completed after the charging of the battery 220 is started (S610).

If the battery 220 is being charged (Yes in S610), the controller 210 may determine the charging current of the battery 220 (S620).

The controller 210 may determine a plurality of SOCs based on the pre-trained mathematical model using the charging current of the battery 220 determined as described above (S630). The plurality of SOCs may be the plurality of SOC values determined by combining the charging current of the battery 220 determined above with a plurality of idle times and the polarization values of the battery 220 corresponding to respective idle times.

The controller 210 may determine, among the plurality of SOCs determined as described above, the SOC that satisfies a preset criterion in terms of difference from the actual SOC of the battery 220 as the second SOC (S640). For example, in an embodiment of the present disclosure, the controller 210 may determine, among the plurality of SOCs determined based on the pre-trained mathematical model for the charging current of the battery 220, the SOC that has the smallest difference from the actual SOC of the battery 220 as the second SOC. The actual SOC of the battery 220 may refer to a reference SOC measured under the same state of the battery 220 as the training data used to train the mathematical model. Only, the actual SOC is obtained through a method or an apparatus other than those used to obtain the training data. The actual SOC may also be determined based on an evaluation of the battery state performed during the manufacturing of the battery 220. The trained mathematical model may inherently include or account for information on the difference between the second SOC and the actual SOC of the battery 220 described above. However, this is an embodiment and is not necessarily limited thereto.

If the charging process of the battery 220 is completed (YES in S610), the controller 210 may determine the charging current of the battery 220, an arbitrary idle time, and the polarization of the battery 220 at the corresponding idle time (S650). As described above, the idle time may refer to the elapsed time after the charging of the battery 220 is completed. The idle time may be arbitrarily determined by the controller 210. In addition, the idle time may be defined as a period from the time the charging of the battery 220 is completed to the time the voltage variation of the battery 220 converges to below a preset reference value. However, this is an embodiment and is not necessarily limited thereto.

Subsequently, the controller 210 may determine the second Soc based on a pre-trained mathematical model for the charging current of the battery 220, an arbitrary idle time, and the polarization of the battery 220 determined at the corresponding idle time, as determined above (S660).

The controller 210 may determine whether SOC correction is necessary based on whether a difference between the first SOC determined by the coulomb counting method and the second SOC satisfies a preset criterion (S670). For example, in an embodiment of the present disclosure, if the difference between the first Soc and the second SOC exceeds a preset value (Yes in S670), the first SOC may be corrected (S680). If the difference is equal to or less than the preset value (No in S670), the first Soc may not be corrected, and the completion of battery charging may be re-determined (S610). In particular, the process shown in FIG. 6, may be intended to correct the first SOC when the difference between the first soc and the second SOC is significant enough to require correction. For example, if the difference between the first SOC and the second SOC is 18, the first SOC may be considered reliable. However, if the difference between the first SOC and the second SOC is 10% or more, the first SOC may be difficult to consider reliable. In other words, the above condition is applied to correct the first SOC when the first SOC is difficult to consider reliable.

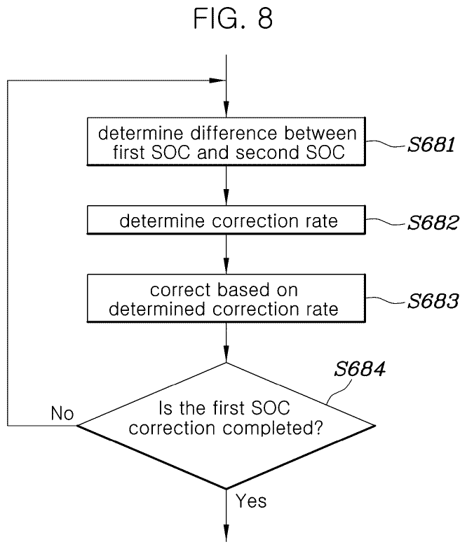

If the difference between the first SOC and the second SOC satisfies a preset criterion (Yes in S670), the controller 210 may correct the first SOC (S680). In an embodiment of the present disclosure, the controller 210 may not instantly correct the first SOC to the second SOC, but rather gradually correct the first Soc by preset SOC change increments at preset time interval. The preset SOC change increments may be smaller than the difference between the first Soc and the second SOC and may be determined according to the difference between the first SOC and the second SOC. However, this is an embodiment and is not necessarily limited thereto. The process by which the controller 210 corrects the first SOC is described in more detail below with reference to FIG. 8.

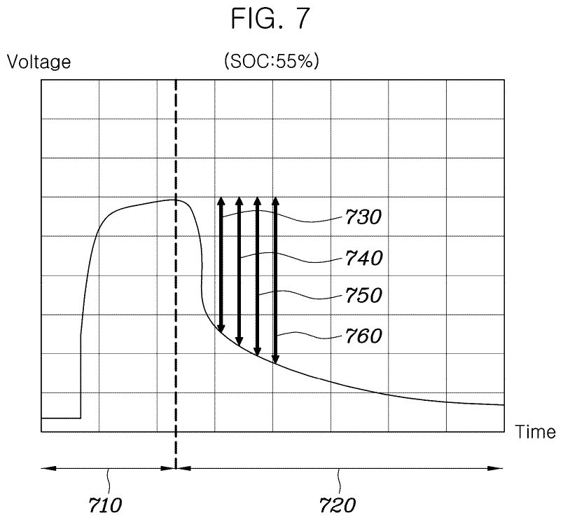

FIG. 7 is a graph showing a process in which the controller 210 determines polarization of the battery 220 based on an idle time after the charging of the battery 220 is completed according to an embodiment of the present disclosure.

Referring to FIG. 7, similar to FIG. 4, the change in the voltage of the battery 220 over time is shown in a state 710 in which the battery 220 is being charged and a state 720 in which charging is completed. However, in contrast with FIG. 4, the state 710 in which the battery 220 is being charged and the state 720 in which charging of the battery 220 is completed represent times during the process in which the controller 210 corrects the SOC in real time, rather than during the process of determining training data.

The idle time may include one or more periods and may be arbitrarily determined by the controller 210 or determined at preset time intervals from the time the charging of the battery 220 is completed. The controller 210 may determine the polarization of the battery 220 for respective idle times. For example, in an embodiment of the present disclosure, the controller 210 may subtract the voltage of the battery 220 determined at respective idle times from the voltage at the time the charging of the battery 220 is completed and determine the resulting difference as the polarization of the battery 220. In addition, as shown in FIG. 7, the controller 210 determines a total of four polarizations 730, 740, 750, 760 corresponding to idle times determined according to preset time intervals. However, this is an embodiment that shows the process by which the controller 210 determines the second SOC using the corresponding polarizations and is not limited thereto. The process by which the controller 210 determines the second SOC after the charging of the battery 220 is completed is described in more detail below with reference to FIG. 7.

The controller 210 may determine the second SOC at respective idle times. For example, in an embodiment of the present disclosure, the controller 210 may determine the second SOC at respective idle times based on a pre-trained mathematical model for the charging current determined in the state 710 in which the battery 220 is being charged, respective idle times, and the polarization 730, 740, 750, 760 of the battery 220 determined at the corresponding idle times. The controller 210 may determine the first Soc based on each determined second SOC. However, this is an embodiment and is not necessarily limited thereto.

In addition, if the intervals between respective idle times are too short, the controller 210 may encounter difficulties in correcting the first Soc based on the second SOC corresponding to each idle time. For example, if the values of the respective second SOCs are similar to each other, the first SOC may be corrected reliably. However, if the values of the respective second SOCs vary significantly, it may be difficult to clearly determine the correction criteria for the first SOC. Accordingly, to enable the controller 210 to correct the first Soc more reliably, in an embodiment of the present disclosure, the idle time may be determined at preset time intervals within the range from the time the charging of battery 220 is completed to the time the voltage variation of the battery 220 remains below a preset value. The controller 210 may determine whether the difference between the first SOC and each previously determined second SOC at respective idle times exceeds a preset value, determine one or more correction rates based on the difference from the first SOC for each second SOC exceeding the preset value, and correct the first Soc based on an average of the one or more correction rates. However, this is an embodiment and is not necessarily limited thereto. The process of correcting the first SOC based on the correction rate is described in more detail with reference to FIG. 8 below.

FIG. 8 is a graph showing a process in which the controller 210 corrects the first soc based on the second SOC according to an embodiment of the present disclosure.

Referring to FIG. 8, the controller 210 may first determine the difference between the first SOC and the second SOC (S681).

Subsequently, the controller 210 may determine the correction rate based on Table 1 below (S682).

TABLE 1

| Condition | Correction Rate |
|---|---|
| 5 ≤ \|ε\| < 10 | ±2% |
| 10 ≤ \|ε\| < 15 | ±3% |
| 15 ≤ \|ε\| | ±4% |

Referring to Table 1, ε is the difference between the first SOC and the second SOC. The controller 210 may determine the correction rate based on the condition satisfied by E. However, this is an embodiment and is not necessarily limited thereto. This is intended to prevent a driver from being confused by changes in soc by gradually correcting the first SOC to approach the second SOC, rather than instantly correcting the first SOC to the second SOC. For example, if the first SOC is 30% and the second SOC is 70%, and the first SOC is corrected from 30% to 70% at once, the driver is highly likely to mistakenly perceive this as a system error in the controller 210. However, as described above, if the first SOC is gradually corrected based on a preset correction rate, the driver perceives that the controller 210 is accurately and reliably correcting the SOC.

The controller 210 may gradually correct the first SOC to match the second SOC based on the determined correction rate (S683). For example, referring to Table 1, if the first SOC is 10% and the second SOC is 23%, the correction rate is +3%, and the controller 210 may increase the first SOC by 3% at each preset time interval. If the first SOC exceeds 13% during the correction of the first Soc, the difference from the second SOC becomes less than 10%, so the correction rate may be changed to 2% per time interval. In this manner, by applying a correction rate for each range based on the SOC difference until the first SOC reaches the second SOC, the first SOC may gradually converge to the second SOC. However, the conditions and corresponding correction rates presented in Table 1 are merely embodiments provided for ease of understanding and are not limited thereto.

In addition, the second SOC may vary due to factors such as changes in variables input to the estimation model depending on the battery usage, and accordingly, the difference between the last-corrected first Soc and the second SOC may also vary. Even if a discrepancy between the first SOC and the second SOC occurs due to such variation in the second SOC, correction rates for respective ranges based on SOC differences may still be applied. Accordingly, the controller 210 may determine a correction rate based on the difference between the changed second SOC and the first SOC whenever the second SOC varies and may gradually correct the first SOC so that the first SOC converges to the second SOC based on the determined correction rate.

The series of processes (S681, S682, S683) in which the controller 210 corrects the first soc based on the previously determined correction rate to cause the first SOC to match the second SOC, as described above, is configured to be completed within a preset time. For example, in an embodiment of the present disclosure, if the controller 210 corrects the first SOC based on the determined correction rate, a certain level of delay time may occur due to operation processing and data loading time within the controller 210. However, this is an embodiment and is not necessarily limited thereto.

The controller 210 may determine whether the first Soc matches the second SOC (S684). The controller 210 may terminate SOC correction if the first SOC matches the second SOC (Yes in S684).

If the first SOC does not match the second SOC (No in S684), the controller 210 may determine the difference between the first SOC to which the correction rate is applied and the second SOC (S681). The controller 210 may perform the correction of the first Soc, to which the correction rate is applied, again. In other words, the controller 210 may iteratively perform the correction of the first Soc until the first SOC matches the second SOC.

The battery management device may include a non-transitory memory (not shown) specifically configured to store computer-executable instructions and various types of data for controlling the vehicle 200 and at a request of the controller 210, read and record data.

The battery management device may further include a processor (not shown) coupled with the memory and specifically configured to implement the controller 210 and perform overall control of the vehicle 200, the battery 220, and the sensors including the current sensor. The memory is configured to store computer-executable instructions that cause the processor to perform/execute methods and functions according to the various embodiments of the present disclosure. In particular, the operations of the vehicle 200, the battery 220, and the sensors, e.g., the current sensor, may be controlled by the computer-executable instructions stored in the memory and executed by the processor.

The processor may have at least one processing module, and each control-related function may be implemented in a single processing module or may be implemented in a corresponding processing module among a plurality of modules. In relation to the present disclosure, the processor may control vehicle to correct the first battery Soc by using an application, an instruction, and/or data stored in the memory. A person having ordinary skill in the art should appreciate that one or more modules, or units described herein may be implemented using, among other things, a tangible computer-readable medium, e.g., the memory, comprising computer-executable instructions (e.g., executable software code). Alternatively, modules may be implemented as software code, firmware code, specifically configured hardware or processors, and/or a combination of the aforementioned.

According to the embodiments described above, it should be understood that the present disclosure provides technology and technical solutions that derive a more accurate and reliable SOC by utilizing the polarization phenomenon of the battery 220. As described above, the SOC determined by a trained mathematical model using training data generated based on the polarization phenomenon of the battery 220 may have higher reliability than conventional methods such as the coulomb counting method and based thereon, the SOC is corrected more efficiently.

As described above, although the spirit or technical scope intended to be provided by the present disclosure has been illustrated and described with reference to various embodiments, it should be apparent to those of ordinary skill in the art that various modifications and changes may be made without departing from the technical spirit provided by the claims below.

What is claimed is:

1. A battery management device comprising:
a battery;
a sensor configured to measure a state of the battery; and
a controller configured to
determine a first state of charge (SOC) of the battery based on the state of the battery cumulatively measured through the sensor, and
correct the first soc based on a second SOC of the battery determined based on a pre-trained model with selective use of a current and a voltage of the battery based on whether the battery is being charged.

2. The battery management device of claim 1,
wherein the voltage includes voltages at respective idle times,
wherein each idle time of the respective idle times includes a time elapsed after completion of charging of the battery, and
wherein the current includes a charging current during charging of the battery.

3. The battery management device of claim 2, wherein the pre-trained model is trained to determine an SOC of the battery based on a relationship between the charging current of the battery and voltages at respective idle times.

4. The battery management device of claim 2, wherein the pre-trained model includes information on a difference between the second SOC and a third SOC determined based on results of an evaluation of the battery state performed during manufacturing of the battery, wherein the second SOC is determined based on the battery state being used as a reference.

5. The battery management device of claim 4, wherein the controller is configured to determine the second SOC among a plurality of SOCs determined based on the pre-trained model using the charging current, based on the battery being charged, as an SOC that satisfies a preset criterion for a difference from the third SOC.

6. The battery management device of claim 2, wherein the controller is configured to, based on the charging of the battery being completed, determine the second SOC based on the pre-trained model using the charging current and voltages at respective idle times.

7. The battery management device of claim 1, wherein the controller is configured to correct the first SOC based on whether a difference between the first SOC and the second SOC satisfies a preset criterion.

8. The battery management device of claim 1, wherein the controller is configured to correct the first Soc until the first Soc converges to the second SOC based on a preset rate of SOC change per unit time.

9. The battery management device of claim 8, wherein the preset rate of SOC change per unit time is determined based on a difference between the first SOC and the second SOC.

10. A method of controlling a battery, the method comprising:
determining, by a controller, a first state of charge (SOC) of the battery based on a state of the battery cumulatively measured through a sensor that measures the state of the battery; and
correcting, by the controller, the first soc based on a second SOC of the battery determined based on a pre-trained model with selective use of a current and a voltage of the battery based on whether the battery is being charged.

11. The method of claim 10,
wherein the voltage includes voltages at respective idle times,
wherein each idle time of the respective idle times is a time elapsed after completion of charging of the battery, and
wherein the current includes a charging current during charging of the battery.

12. The method of claim 11, wherein the pre-trained model is trained to determine an SOC of the battery based on a relationship between the charging current of the battery and voltages at respective idle times.

13. The method of claim 11,
wherein the pre-trained model includes information on a difference between the second SOC and a third SOC determined based on results of an evaluation of the battery state performed during manufacturing of the battery, and
wherein the is used as a reference when determining the second SOC.

14. The method of claim 13, wherein correcting the first SOC based on a second SOC of the battery includes:
determining, by the controller, based on the battery being charged, the second SOC among a plurality of SOCs determined based on the pre-trained model using the charging current, as an SOC that satisfies a preset criterion for a difference from the third SOC.

15. The method of claim 11, wherein correcting the first Soc, based on a second SOC of the battery includes:
determining, based on the charging of the battery being completed, by the controller, the second SOC based on the pre-trained model using the charging current and voltages at respective idle times.

16. The method of claim 10, wherein correcting the first SOC includes correcting, by the controller, the first SOC based on whether a difference between the first SOC and the second SOC satisfies a preset criterion.

17. The method of claim 10, wherein correcting of the first SOC includes correcting, by the controller, the first SOC until the first Soc converges to the second SOC based on a preset rate of SOC change per unit time.

18. The method of claim 17, wherein the preset rate of SOC change per unit time is determined based on a difference between the first SOC and the second SOC.
